(19) United States
(12) Patent Application Publication
(10) Pub. No.: US 2023/0131705 A1
(43) Pub. Date: Apr. 27, 2023

(54) AIRCRAFT HOLD COMPRISING AT LEAST ONE LONGITUDINALLY DISPOSED AND TRANSVERSELY MOVABLE CABINET, AND METHOD FOR THE ARRANGEMENT OF SAID HOLD

(71) Applicant: Airbus Operations SAS, TOULOUSE (FR)

(72) Inventors: Patrick SALGUES, TOULOUSE (FR); Didier DETHUNE, TOULOUSE (FR)

(21) Appl. No.: 17/964,986

(22) Filed: Oct. 13, 2022

(30) Foreign Application Priority Data
Oct. 21, 2021 (FR) 2111169

(51) Int. Cl. B64C 1/06; B64D 43/00

(52) U.S. Cl. CPC B64C 1/06; B64D 43/00

(57) ABSTRACT

A hold of an aircraft includes at least two system cabinets, one cabinet is disposed longitudinally. The longitudinal cabinet is movable between a use position along a wall of the fuselage and a maintenance position, in which it is spaced apart from the wall of the fuselage. This arrangement makes it easier to access the system cabinets installed in the hold of the aircraft by the operators arranging the hold or carrying out maintenance on the cabinets.

### CROSS-REFERENCES TO RELATED APPLICATIONS

This application claims the benefit of the French patent application No. 2111169 filed on Oct. 21, 2021, the entire disclosures of which are incorporated herein by way of reference.

### FIELD OF THE INVENTION

The present invention relates to the field of hold arrangement and the installation of system cabinets or bays in aircraft and in particular transport airplanes.

### BACKGROUND OF THE INVENTION

In an aircraft, the generic term “system cabinet” denotes a cabinet or bay intended for the integration of electrical and electronic equipment. The cabinet is very often in the form of an enclosure. Among the system cabinets present in an aircraft, there are, for example, avionics cabinets comprising equipment intended for the flight-control of the aircraft. The avionics cabinets are generally positioned in the nose in the vicinity of the cockpit and, more specifically, generally in the hold, referred to as the avionics hold, arranged under the floor of the cockpit.

The patent FR2963314 filed by the applicant describes a method and a device for the arrangement of an avionics hold 2 in which the system cabinets 4, which are installed transversely, follow one another longitudinally. As can be seen in FIG. 1, the main avionics cabinet 6, which is positioned transversely, is bulky and blocks the passage. In order to access the different cabinets, the operator has to pass either through the cargo hold or through a hatch.

The patent EP2474476 discloses a method and device for accessing an equipment rack from outside the aircraft. The fuselage is cut in order that the equipment rack and a part of the fuselage moves laterally outward.

The patent EP1876875 discloses an equipment rack system comprising a movable rack and a cage for containing and immobilizing the rack.

### SUMMARY OF THE INVENTION

The present invention aims to provide a hold that makes it easier for the cabinets to be accessed by the operators for the arrangement of the hold or in order to carry out maintenance operations without it being necessary to provide such hatches, and the resultant arranging method.

To this end, the present invention relates to an aircraft hold comprising at least two system cabinets, wherein one cabinet, referred to as the longitudinal cabinet, is disposed longitudinally and wherein the cabinet is movable transversely between a position referred to as the use position along a wall of the fuselage and a position referred to as the maintenance position, in which it is spaced apart from the fuselage wall.

The invention provides at least one of the following optional features, taken individually or in combination.

The hold comprises another, transversely disposed cabinet, referred to as the transverse cabinet, so as to leave a space free between the two, transverse and longitudinal cabinets, allowing the passage of a person.

The longitudinal cabinet is mounted on at least one transverse slideway allowing it to move transversely.

Locking means are provided to keep the longitudinal cabinet in at least two positions comprising the use position and the maintenance position.

The longitudinal cabinet comprises at least one beam on its lower face, which is capable of sliding inside rail(s) provided for each beam on the floor of the hold, the rail or rails being provided with rollers to make sliding easier.

The beam or beams and the rail or rails respectively have through-orifices next to which it is possible to introduce locking keys for preventing the beam from moving with respect to the rail, the orifices being positioned so as to keep the cabinet in a given position.

Electric wiring harnesses are held above the longitudinal cabinet by supporting devices, allowing them to be released easily to enable the transverse movement of the cabinet without being impeded by the harness on account of its position above the cabinet.

The present invention also relates to a method for arranging an aircraft hold having at least one of the preceding optional features, taken individually or in combination, which comprises a step of installing the longitudinal system cabinet longitudinally in the hold such that it is movable between the use position along the wall of the fuselage and the position referred to as the maintenance position, in which it is spaced apart from the fuselage wall.

The invention provides at least one of the following optional features, taken individually or in combination.

The method comprises a step of installing the transverse cabinet in line with the longitudinal cabinet so as to leave a space free between the two, transverse and longitudinal cabinets, allowing the passage of a person.

The step of installing the longitudinal cabinet begins before the step of installing the transverse cabinet, the production of which may continue in parallel outside the aircraft.

### BRIEF DESCRIPTION OF THE DRAWINGS

Other aims, features and advantages will become apparent from the following description of the invention, which is given solely by way of nonlimiting example with reference to the accompanying drawings, in which:

FIG. 1 is a partial simplified perspective view from above, at a particular viewing angle, of a hold arrangement according to the prior art;

FIG. 2 is a transparent schematic perspective view from above, at a certain viewing angle, of a nose, showing the difference between the arrangement of a hold according to the prior art on the left and the arrangement of a hold according to the present invention on the right;

FIG. 3 is a partial schematic view from above of the hold, revealing the transverse movement of a longitudinal cabinet of the hold;

FIG. 4 is a schematic side view of a longitudinal cabinet of the hold according to the present invention.

### DETAILED DESCRIPTION OF THE PREFERRED EMBODIMENTS

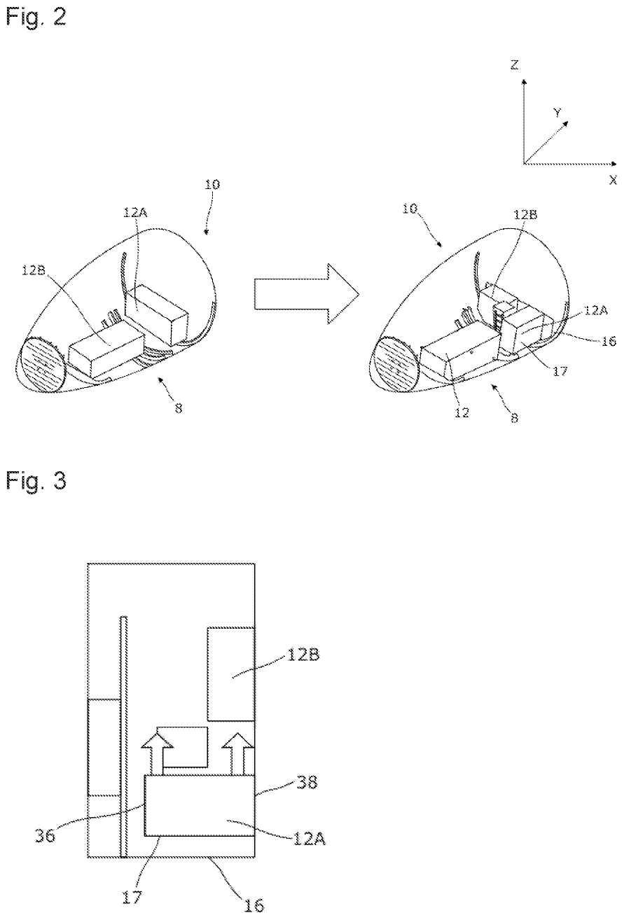

As shown in FIGS. 2 to 4, the present invention relates to the arrangement of a hold 8 in an aircraft 10. The following description refers to an orthonormal frame of reference X, Y, Z (visible in FIG. 2) in which the horizontal directions X, Y and vertical direction Z are defined with reference to an aircraft standing on horizontal ground. The three directions X, Y, Z are mutually orthogonal. The fuselage of the aircraft extends along a longitudinal direction X. The direction Y corresponds to the direction oriented transversely and horizontally with respect to the longitudinal direction X. The direction Z corresponds to the vertical direction or height. As a qualifier for longitudinal and transverse, respectively, vertical means parallel to the longitudinal or transverse vertical direction, respectively. The terms front and rear are considered with respect to the direction of the aircraft in flight. Throughout the description, the terms “upper” and “lower” are understood with reference to this frame of reference X, Y, Z and more particular to the direction Z. The term hold is understood with a very generic meaning, namely the space in the fuselage which is located beneath a floor, for example that of the cockpit and/or of the passenger cabin, and in which system cabinets are disposed. The hold may also serve to store luggage or equipment.

Throughout the rest of the description, a system cabinet 12 is understood to be a cabinet or bay containing systems of multiple types such as electrical, electronic, optical and/or the like, for storing and processing data of one or more types. The data processed may be for example avionic data, namely flight-control data. Another example of data managed in system cabinets may be in-flight entertainment (IFE) data, namely data intended for the comfort of the passengers. The hold 8 comprises at least two system cabinets 12.

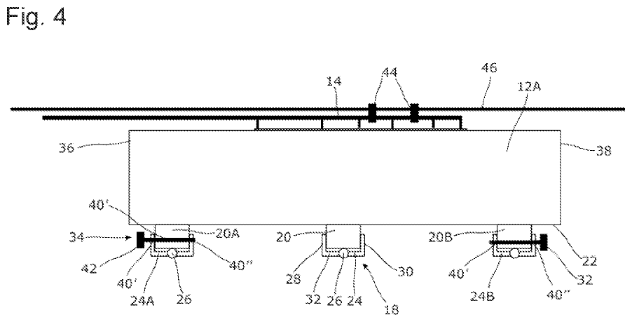

The system cabinets 12 are generally in the form of parallelepipedal enclosures of rectangular section. However, the cabinet may have a different section. According to one possible embodiment, the enclosures contain computers, electrical and electronic components in the form of a rack, and cables run to the enclosures in bundles referred to as harnesses 14 (visible in FIG. 4). The harnesses 14 generally connect the system cabinets 12 to control members associated with the cockpit for the avionic data or with IFE terminals in the cabin for the IFE data, or with other components depending on the type of data.

As illustrated in FIGS. 2 and 3, the hold 8 according to the present invention comprises a cabinet 12A disposed in a longitudinal direction along a wall 16 of the fuselage of the aircraft 10, referred to as longitudinal cabinet 12A. “Disposed in a longitudinal direction” means that, in horizontal section, the greatest length of the cabinet lies in a longitudinal direction. The length is the straight-line segment located between two extreme points of the cabinet along a single horizontal longitudinal axis. Moreover, “along a wall of the fuselage” means that the cabinet is disposed transversely closer to one longitudinal wall of the aircraft than to the other. According to one embodiment, the central longitudinal axis of the cabinet is located transversely closer to a wall of the fuselage than to the central longitudinal axis of the aircraft or, according to another embodiment, in the third transversely closest to a wall of the fuselage. The longitudinal cabinet is shown in a use position and is movable between the use position and a position referred to as the maintenance position, in which it is spaced apart from the wall 16 of the fuselage. In this way, a passage is opened up for the operators between the wall 16 of the fuselage and the cabinet 12A in order to access the external face 17 of the cabinet. The external face 17 of the cabinet is the face facing toward the exterior of the aircraft. The movement of the longitudinal cabinet 12A from the use position to the maintenance position is indicated by arrows in FIG. 3.

The hold 8 comprises another, transversely disposed system cabinet 12B, referred to as the transverse cabinet 12B. The cabinet 12B is positioned in the hold so as to leave a space free between the transverse cabinet 12B and longitudinal cabinet 12A in the use position, allowing a person to pass between these cabinets. According to one embodiment, the transverse system cabinet 12B is disposed so as to lie longitudinally in line with the longitudinal cabinet. “To be in line with” means that if the transverse cabinet were extended virtually in the transverse direction, it would be blocked by the longitudinal cabinet. According to one possible embodiment as illustrated in FIGS. 2 and 3, in views from above, the two, transverse and longitudinal cabinets form an L-shape. Any other arrangement is possible, for example a T-shape. In the maintenance position, the longitudinal cabinet is spaced apart from the wall 16 of the fuselage and is located closer to the transverse cabinet 12B. The space created between the wall of the fuselage and the exterior face of the longitudinal cabinet in the maintenance position eliminates the space provided in the use position between the longitudinal and transverse cabinets. In the use position, the space provided between the transverse cabinet and the longitudinal cabinet allows easy passage to the rear of the hold in order, for example, to access the rear of the transverse cabinet or the front of the latter depending on where the operator is positioned. Since there is now access to the front and rear faces of the transverse cabinet, it is also possible to provide a door in the fuselage rather than a hatch to allow the operator to enter the hold.

According to one embodiment illustrated in FIG. 4, the longitudinal cabinet 12A is mounted on at least one slideway 18 disposed transversely in the hold, allowing it to be moved transversely. Numerous embodiments of the slideway of known type are possible. FIG. 4 shows one. The cabinet 12A comprises at least one beam 20 on its lower face 22, which is capable of sliding inside a rail 24 associated with each beam and provided on the floor of the hold. The beam or beams are fixed to the cabinet by any type of means. They may also form part of the cabinet. The rails 24 are equipped with rollers 26. Placed between each beam and the associated rail, the rollers 26 allow the beam to slide along the rail. In the embodiment illustrated, three beams 20 are provided. Each rail 24 has a U-shaped section; in the embodiment illustrated, each rail is in the form of a half-rectangle, into the groove of which the associated beam 20 of corresponding rectangular section is inserted. The rail 24 with a U-shaped section comprises two parallel arms 28, 30 connected by a web 32.

Locking means 34 are provided to keep the longitudinal cabinet 12A in position at least in the use position and in the maintenance position. Other positions may be envisioned between the use position and the maintenance position. The locking means need to be able to allow easy locking/unlocking. According to the embodiment of the locking means illustrated in FIG. 4, for the beams 20A, 20B located closest to the front face 36 and rear face 38 of the cabinet 12A, each beam 20A, 20B and each arm 28, 30 of the corresponding rail 24A, 24B respectively have through-orifices 40′, 40″ into which a locking key 42 can be introduced. The orifices 40′, 40″ in the beam 20A, 20B and the arms 28, 30 of the rail 24A, 24B, respectively, are positioned opposite one another when the cabinet 12A reaches one of the desired positions and in particular the use position and the maintenance position. Only the beams 20A, 20B located closest to the front 36 and rear face 38 of the cabinet are pierced so as to be readily accessible for the insertion of the key 42. The through-orifices (40′), (40″) are positioned so as to be located opposite one another in order to keep the cabinet in a given position.

The electric wiring harnesses 14 are held above the longitudinal cabinet 12A, as illustrated in FIG. 4, by supporting devices 44. In the embodiment illustrated, they are held on the structure 46 of the floor by the supporting devices 44. The supporting devices 44 of any known type are disposed so as to be easily accessible by an operator in order to allow quick and easy disconnection of the structure to which they are fixed and to allow the longitudinal cabinet to be moved transversely without being impeded by the harness. The supports may be in a very large number of forms, such as a hooked strap held by a device fixed to the structure 46: in this embodiment, all that is required is to detach the strap to release the harness.

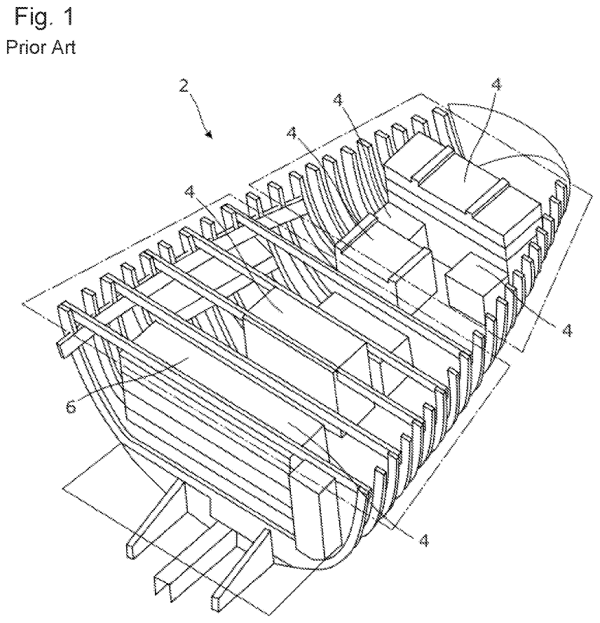

As set out above and illustrated in FIG. 1, the transversely positioned rear system cabinet 6 according to the prior art extends across a major part of the width of the aircraft and so prevents the passage of the operators. It extends across such a width of the fuselage that it prevents operators from passing longitudinally from one side of the transverse cabinet to the other. The arranging method according to the present invention comprises a step of dividing such a cabinet such as this transversely disposed cabinet 6 into two cabinets such that the transversely disposed cabinet 12B, referred to as the transverse cabinet 12B, and longitudinally disposed cabinet 12A, referred to as the longitudinal cabinet 12A, are far enough from one another to allow a person to pass between them in the longitudinal direction. The systems of a cabinet are distributed over two cabinets 12A, 12B with smaller external dimensions, or of smaller size. In the rest of the description, the two cabinets 12A, 12B, one installed longitudinally and the other transversely, are considered to be two independent cabinets, without taking into consideration the fact that they do or do not originate from one and the same original cabinet redesigned to distributed the internal systems thereof over two different cabinets.

The arranging method comprises a step of installing one of the two cabinets in the hold, making it possible to continue the production of the other, if necessary, outside the airplane. In addition to saving time for arranging the hold, the operators can move around the cabinet installed in the hold more easily because the other cabinet is still on the ground. However, if the two cabinets are ready, they can be installed in the hold at the same time.

The arranging method comprises a step of installing one cabinet, the transverse cabinet, in a transverse direction, and a step of installing one cabinet, the longitudinal cabinet, in a longitudinal direction. According to one embodiment, a space is provided between the two to allow the passage of a person. As set out above, the steps may be simultaneous or in succession, it being possible for the transverse cabinet to be installed before the longitudinal cabinet or vice versa. According to one possible embodiment, the step of installing the longitudinal cabinet begins before the step of installing the transverse cabinet, the production of which may continue in parallel outside the aircraft. In this way, the operator may move freely around the longitudinal cabinet in the maintenance position while the transverse cabinet is not installed.

The arranging method comprises a step of fixing at least one rail 24 in a transverse direction in the hold 8 and a step of producing a cabinet 12 provided with at least one beam 20, the beam either being part of the cabinet or attached thereto by any type of fixing means. Rollers 26 are attached to or are an integral part of the rail or rails 24. According to one embodiment, the method comprises a step of installing the longitudinal cabinet 12A provided with beam(s) 20 on the rail or rails 24 provided in the hold and, according to one embodiment, before the installation of the transverse cabinet. The beam or beams 20 are inserted into the corresponding rail or rails 24. On account of the presence of the rollers 26, the longitudinal cabinet, pushed or pulled by an operator, slides easily in the transverse direction. The cabinet is then stopped from moving and locked in the maintenance position and the operator can move around the cabinet to complete its installation in the hold. The cabinet is then unlocked and positioned and locked in the use position in order to carry out the step of installing the transverse cabinet.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A hold of an aircraft comprising:
at least two system cabinets,
wherein a longitudinal cabinet of the two system cabinets is disposed with a longest horizontal extent of the longitudinal cabinet oriented longitudinally within the aircraft hold, and
wherein said longitudinal cabinet is movable transversely with the aircraft hold between a use position, in which the longitudinal cabinet is arranged along a wall of a fuselage of the aircraft and a maintenance position, in which the longitudinal cabinet is spaced apart from the wall of the fuselage, such that a passage is opened up between the wall of the fuselage and the cabinet to allow access to an external face of the cabinet, the external face facing toward an exterior of the aircraft.

2. The hold as claimed in claim 1, which comprises a transverse cabinet of the two system cabinets disposed with a longest horizontal extent of the transverse cabinet oriented laterally within the aircraft hold, so as to leave a space free between the transverse and longitudinal cabinets, allowing passage of a person.

3. The hold as claimed in claim 1, wherein the longitudinal cabinet is mounted on at least one transverse slideway allowing the longitudinal cabinet to move transversely.

4. The hold as claimed in claim 1, wherein locking means are provided to keep the longitudinal cabinet in at least two positions, comprising the use position and the maintenance position.

5. The hold as claimed in claim 1, wherein the longitudinal cabinet comprises at least one beam on its lower face, which is capable of sliding inside a rail provided for each at least one beam on a floor of the hold, the rail being provided with rollers to make sliding easier.

6. The hold as claimed in claim 4,
wherein the longitudinal cabinet comprises at least one beam on its lower face, which is capable of sliding inside a rail provided for each at least one beam on a floor of the hold, the rail being provided with rollers to make sliding easier, and
wherein the at least one beam and the rail, respectively, have through-orifices through which it is possible to introduce locking keys for preventing the beam from moving with respect to the rail, the through-orifices being positioned to keep the longitudinal cabinet in a given position.

7. The hold as claimed in claim 1, wherein electric wiring harnesses are held in a position above the longitudinal cabinet by supporting devices, allowing the wiring harnesses to be released easily to enable a transverse movement of the longitudinal cabinet without being impeded by the wiring harnesses on account of the position of the wiring harnesses above the longitudinal cabinet.

8. A method for arranging a hold of an aircraft as claimed in claim 1, which comprises a step of installing the longitudinal cabinet longitudinally in the hold such that it is movable transversely between said use position along the wall of the fuselage and said maintenance position, in which it is spaced apart from the fuselage wall, such that a passage is opened up between the wall of the fuselage and the cabinet to access the external face of the cabinet, the external face facing toward the exterior of the aircraft.

9. The method for arranging a hold as claimed in claim 8, the hold further comprising a transverse cabinet disposed with a longest horizontal extent of the transverse cabinet oriented laterally within the aircraft hold, so as to leave a space free between the transverse and longitudinal cabinets, allowing passage of a person, and the method further comprising a step of installing the transverse cabinet in line with the longitudinal cabinet so as to leave a space free between the transverse and longitudinal cabinets, allowing the passage of a person.

10. The arranging method as claimed in claim 9, wherein the step of installing the longitudinal cabinet begins before the step of installing the transverse cabinet, a production of which transverse cabinet may continue in parallel outside the aircraft.
